(19) United States
(12) Patent Application Publication
(10) Pub. No.: US 2008/0102595 A1
(43) Pub. Date: May 1, 2008

(54) ETCHING METHOD FOR MANUFACTURING SEMICONDUCTOR DEVICE

(75) Inventors: Won-Jun LEE, Seoul (KR); Byoung-Moon YOON, Gyeonggi-do (KR); In-Seak HWANG, Gyeonggi-do (KR); Yong-Sun KO, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/969,105

(22) Filed: Jan. 3, 2008

Related U.S. Application Data
(62) Division of application No. 10/763,356, filed on Jan. 23, 2004, now Pat. No. 7,338,610.

(30) Foreign Application Priority Data
Sep. 22, 2003 (KR) 2003-0065533

(51) Int. Cl. H01L 21/02

(52) U.S. Cl. 438/396; 257/E21.011

(57) ABSTRACT

A wafer having a dielectric layer and an electrode partially protruding from the top surface of the dielectric layer is provided. The dielectric layer is etched with a chemical solution such as LAL. Prior to etching, the protruding portion of the electrode is removed or reduced to prevent any bubbles included in the chemical solution from adhering to the electrode. Thus, the chemical solution can etch the dielectric layers without being blocked by any bubbles included in a chemical solution.

### CROSS-REFERENCE TO RELATED PATENT APPLICATION

This application is a Divisional of U.S. Ser. No. 10/763,356, filed on Jan. 23, 2004, now pending, which claims priority from Korean Patent Application No. 10-2003-0065533, filed on Sep. 22, 2003, all of which are hereby incorporated by reference in their entirety.

### BACKGROUND OF THE INVENTION

1. Field of the Invention

The present invention relates to methods for manufacturing semiconductor devices. More particularly, the present invention relates to etching methods for manufacturing a semiconductor device such as a capacitor lower electrode.

2. Description of the Related Art

In fabricating semiconductor devices such as dynamic random access memory (DRAM) devices, a chemical solution such as one containing HF and NH₄F (“LAL”) or a buffer oxide etchant (“BOE”) is commonly used to etch dielectric layers during various phases of semiconductor fabrication processes.

Unfortunately, air bubbles of various sizes included in the chemical solution often adhere to the surface of a semiconductor substrate, creating serious problems such as an oxide un-etch or not-open phenomenon. As the design rule decreases, this issue becomes more critical, considerably reducing the yield.

Accordingly, an immediate need exists for a novel etching method that can overcome problems caused by air bubbles contained in the chemical solution.

### SUMMARY OF THE INVENTION

The present invention provides improved methods of etching dielectric layers using a chemical solution such as LAL without, for example, an un-etch or not-open phenomenon resulting from any bubbles contained in the chemical solution.

According to one embodiment of the present invention, a wafer having a dielectric layer and an electrode partially protruding from the top surface of the dielectric layer is provided. The dielectric layer is etched with a chemical solution. Prior to etching, the protruding portion of the electrode is removed or reduced. Preferably, the protruding portion of the electrode is removed or reduced sufficiently to prevent any bubbles included in the chemical solution from adhering to the electrode.

According to another embodiment of the present invention, an etching method comprises forming a first dielectric layer on a semiconductor substrate; forming an opening in the dielectric layer; depositing a conductive layer on the dielectric layer including the opening; depositing a second dielectric layer overlying the conductive layer within the opening; planarizing the resulting structure including the conductive layer, until the top surface of the first and second dielectric layers are exposed, to form a capacitor lower electrode; and etching the first and second dielectric layers with a chemical solution. Prior to etching, a top end portion of the electrode is reduced.

As a result of the inventive principles disclosed herein, bubbles contained in a chemical solution can be prevented from adhering to, for example, a capacitor lower electrode during dielectric layer etching processes. Thus, the chemical solution such as LAL can etch the dielectric layers without being blocked by any bubbles included in a chemical solution. Therefore, with the embodiments of the present invention, device failures, such as one bit failure caused by an un-etched phenomenon, can be prevented to increase the yield.

### BRIEF DESCRIPTION OF THE DRAWINGS

The objects and advantages of the present invention will become more apparent by describing in detail preferred embodiments thereof with reference to the attached drawings in which:

FIGS. 1A through 1G are cross-sectional views illustrating an etching method according to an embodiment of the present invention;

FIG. 2A is a cross-sectional view illustrating bubbles included in a chemical solution such as LAL being trapped in a circular capacitor lower electrode;

FIG. 2B is a cross-sectional view illustrating an unetched portion caused by the bubbles present in the chemical solution within the capacitor lower electrode; and

FIG. 2C is a top view of capacitor lower electrode structures of a semiconductor device illustrating a closed storage node contact of FIG. 2B, showing a “not open” phenomenon.

### DETAILED DESCRIPTION OF THE INVENTION

The present invention will now be described more fully with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete and will fully convey the concept of the invention to those skilled in the art. In the drawings, the shape of elements is exaggerated for clarity, and the same reference numerals in different drawings represent the same element.

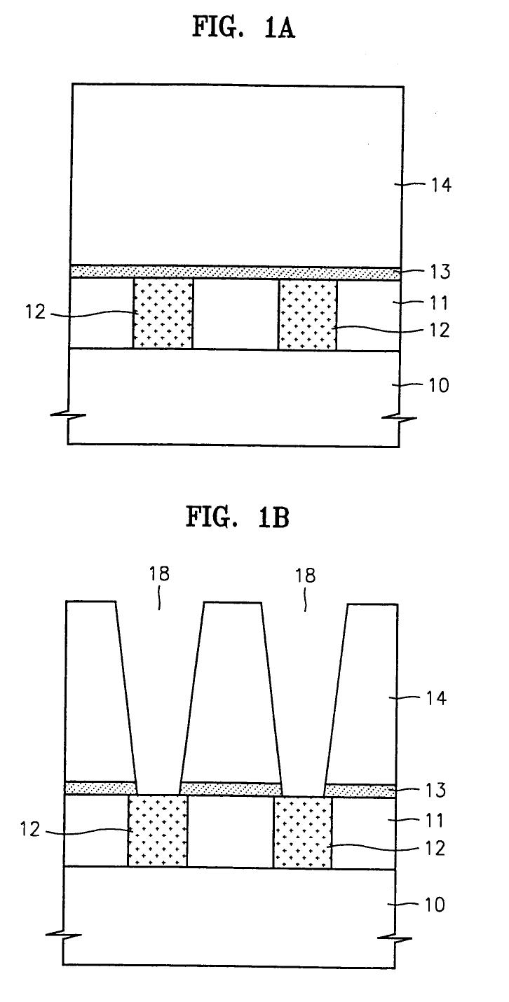

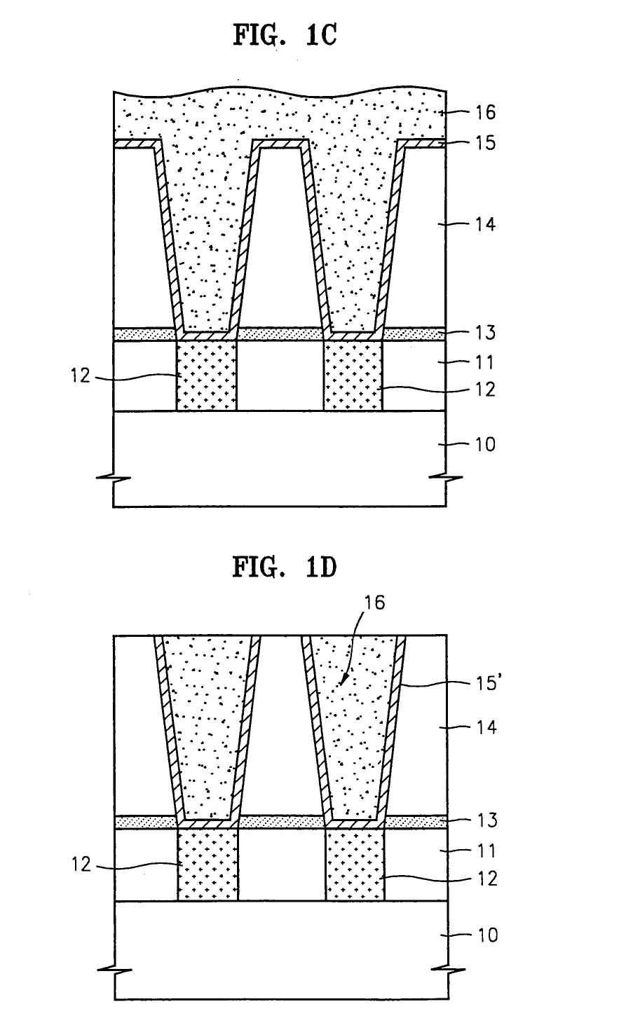

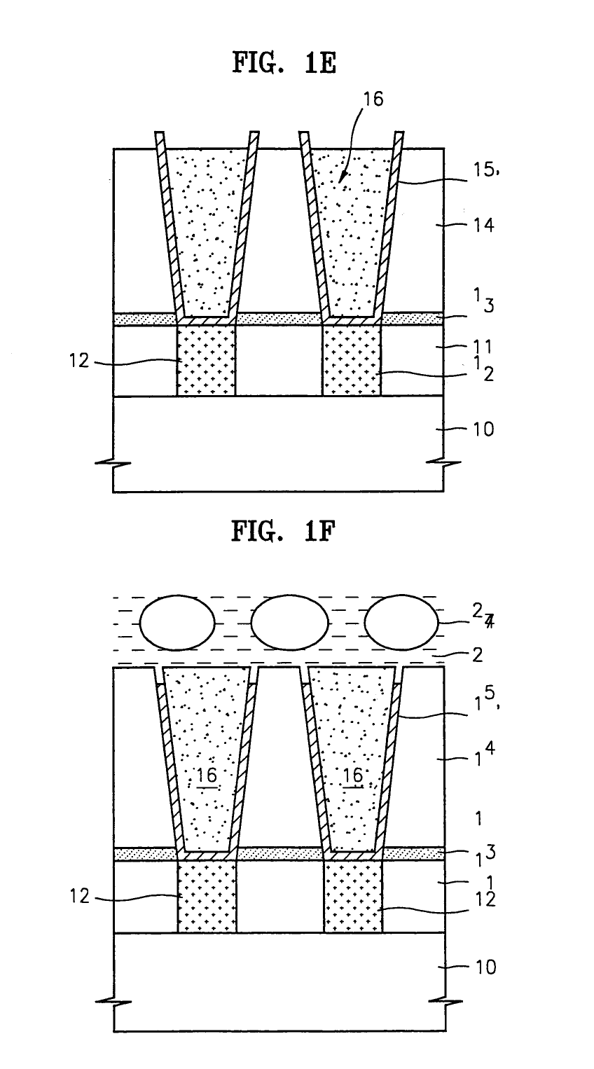

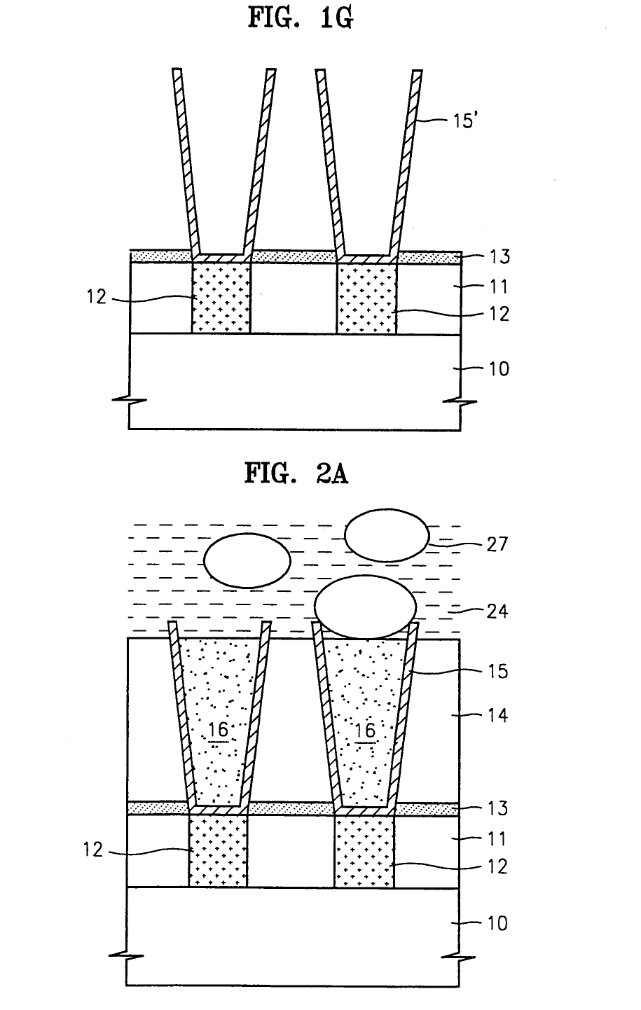

Referring to FIG. 1A, to form a capacitor of a semiconductor device such as dynamic random access memories (DRAMs), an interlayer insulating layer or a pre-metal dielectric layer 11 is formed on a wafer or semiconductor substrate 10. The interlayer insulating layer 11 is formed of a dielectric material such as oxide.

Although not shown, a lower structure such as source/drain regions and gate electrodes are formed on the semiconductor substrate 10 to form a transistor or a memory cell. Then, a storage node contact pad 12 is formed in the interlayer dielectric layer 11 to be electrically connected to a capacitor lower electrode to be formed thereon, using conventional techniques. The storage node contact pad 12 is also electrically connected to active regions of the semiconductor substrate 10.

Subsequently, the interlayer dielectric layer 11 is planarized. An etch stop layer 13 is then formed on the interlayer dielectric layer 11. The etch stop layer 13 has a high etch selectivity with respect to the first dielectric layer 14. These layers can be formed using conventional processes. The etch stop layer 13 can be formed of, for example, silicon nitride to a thickness between about 500 to 1,000 angstroms.

A first dielectric layer 14 is formed on the etch stop layer 13. The etch stop layer 13 serves as an end point during a subsequent etching lift-off process for removing the first dielectric layer 14, as well as second dielectric layer 16 to be formed thereon.

The first dielectric layer 14 is preferably formed of an oxide having a thickness between about 3,000 to 20,000 angstroms using a conventional technique such as a low pressure chemical vapor deposition (LPCVD) process. The first dielectric layer 14 can be a single layer of plasma-enhanced tetraethylorthosilicate (PE-TEOS) or a multilayer including the PE-TEOS layer.

Referring to FIG. 1B, the first dielectric layer 14 is etched or patterned to form a storage node opening 18 therein to expose a portion of the contact pad 12, using conventional photolithography and etching processes, with the etch stop layer 13 as an etch stop. The etch stop layer 13 remaining within the storage node opening 18 is removed.

Referring to FIG. 1C, a conductive layer 15 formed of a material such as doped polysilicon, Pt, Ru, or TiN, is deposited on the first dielectric layer 14 including the opening 18 and on the storage node contact pad 12 to form a capacitor lower electrode 15′. (FIG. 1D) Then, a second dielectric layer 16 is formed on the conductive layer 15 that is connected to the contact pad 12 and within the opening 18. The second dielectric layer 16 is preferably formed of oxide to a thickness between about 10,000 to 30,000 angstroms. Those skilled in the art will appreciate that other suitable dielectric materials can also be used to form the first and second dielectric layers 14, 16.

Turning to FIG. 1D, the first and second dielectric layers 14, 16 including the conductive layer 15 are planarized, until the top surface of the first and second dielectric layers 14, 16 are exposed, so as to form separated capacitor lower electrodes 15′.

The planarization process can be performed using conventional techniques such as chemical mechanical polishing (CMP) or an etching back process. Preferably, CMP comprises using a slurry having an etch selectivity between the capacitor lower electrode 15′ and the first and second dielectric layers 14, 16. Preferably, etching back comprises using an etchant having an etch selectivity between the capacitor lower electrode 15′ and the first and second dielectric layers 14, 16.

Referring to FIG. 1E, HF is preferably used to clean etching back or CMP residues resulting from the planarization process. An upper part of the capacitor lower electrode 15′ having, for example, a circle or elliptical shape may protrude from the surface of dielectric layers 14, 16 because of this wet cleaning process using HF, which selectively etches dielectric layers such as an oxide while substantially leaving the capacitor lower electrode formed of, for example, polysilicon. Other suitable chemicals can also be used to clean the residues as is known in the art.

Referring 1G, the first and second dielectric layers 14, 16 are preferably concurrently removed using a conventional lift-off process to complete the capacitor lower electrode 15′. In particular, the first and second dielectric layers 14, 16 are etched with a chemical solution such as LAL. During this wet etching process, LAL, the composition of which is disclosed in Table 1, is typically used. Other suitable wet etch chemicals besides LAL can be used as is known in the art.

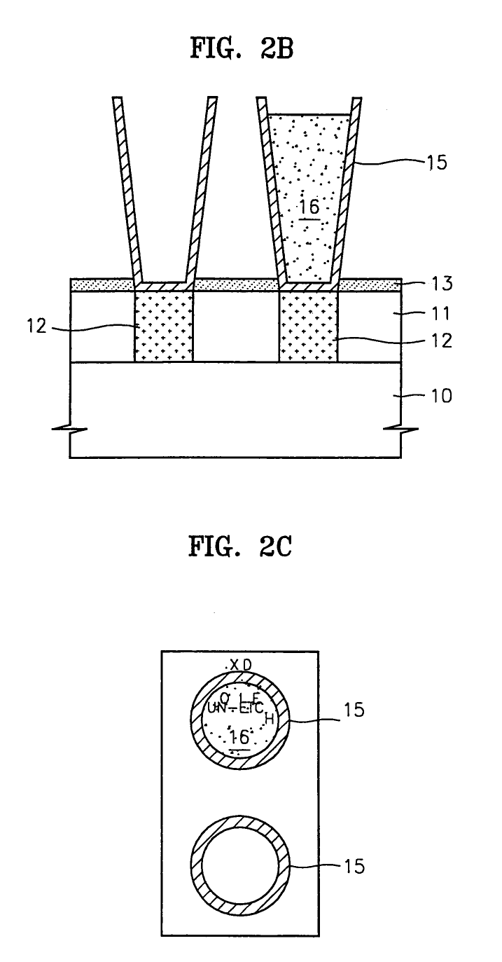

However, unfortunately, bubbles contained in the chemical solution such as LAL can easily adhere to the projected portion of the lower electrode 15′ as shown in FIG. 2A. This is especially true if the lower electrode 15′ is, for example, circular or elliptical in plan view because it can easily trap the bubbles.

This issue becomes more critical, as the design rule further decreases, because these undesirable bubbles trapped in the capacitor lower electrode 15′ prevent the chemical solution such as LAL from contacting the dielectric layer 16, thereby causing an un-etch or not open phenomenon, as shown in FIGS. 2B and 2C. In other words, a portion of the dielectric layers 16 is left unetched because of the bubbles present in the chemical solution, thus preventing the chemical solution from contacting the second dielectric layer 16. This in turn prevents removal of the second dielectric oxide layer 16.

Now turning to FIG. 1F, to deal with the problem described above, according to an embodiment of the present invention, prior to performing a conventional lift-off process, i.e., wet etching to remove the first and second dielectric layers 14, 16, a top end portion of the capacitor lower electrode 15′ is removed or reduced sufficiently to prevent any bubbles included in the chemical solution from adhering to the electrode 15′ or the semiconductor substrate 10.

Preferably, the protruding portion is reduced to recess the top surface of the electrode 15′ below the top surface of the dielectric layers 14, 16 at a depth sufficient enough to prevent any bubbles included in the chemical solution from adhering to the electrode 15′ or the semiconductor substrate 10. Thus, the top surface of the electrode 15′ is lower than the top surface of the first and second dielectric layers 14, 16. More preferably, the lowered (recessed) top surface is at least 500 angstroms below the top surface of the first dielectric layer 14.

Alternatively, the top portion of the capacitor lower electrode 15′ is preferably reduced such that the top surface of the capacitor lower electrode 15′ is substantially level with the top surface of the first dielectric layer 14.

However, one skilled in the art will appreciate that the present invention is not limited to the above-described embodiments. For example, the top surface of the lower electrode 15′ may be slightly above the top surface of the first dielectric layer 14 as long as any bubbles included in the chemical solution can be prevented from adhering to the electrode 15′ or to the semiconductor substrate 10 by reducing the top end portion of the capacitor lower electrode 15′.

According to another embodiment of the present invention, the protruding portion is reduced using dry etching. Preferably, the drying etching uses an etchant selected from the group consisting of HB₄, Cl₂, CF₄, C₄F₈, C₅F₈, SF₆, O₂, and combinations thereof. Alternatively, the protruding portion is reduced using wet etching. Preferably, wet etching uses a polysilicon etchant. 24.

According to another aspect of the present invention, the top end portion of the electrode 15′ may be reduced in situ while the etching back process is performed to planarize the first and second dielectric layers 14, 16, as described above with reference to FIG. 1D. This can be accomplished by, for example, increasing the poly etchant component.

Alternatively, the top end portion of the electrode 15′ may be reduced in situ while the CMP is performed to planarize the first and second dielectric layers 14, 16, as described above with reference to FIG. 1D. For example, the CMP can be performed as two-step processes. In other words, a conventional CMP process is performed until the resulting structure is planarized. Then, the top end portion of the electrode 15′ can be reduced by increasing the poly etchant component of the CMP slurry.

However, the present invention is not limited to the above described embodiments. One skilled in the art will appreciate that other suitable methods to reduce the top end portion of the electrode 15′ can be equally applicable to the present invention.

As a result of the inventive principles disclosed herein, bubbles contained in a chemical solution can be prevented from adhering to, for example, a capacitor lower electrode during dielectric layer etching processes. Thus, the chemical solution such as LAL can etch the dielectric layers without being blocked by any bubbles included in a chemical solution.

Therefore, with the embodiments of the present invention, device failures, such as one bit failure caused by an un-etched phenomenon, can be prevented. Therefore, the yield can be significantly increased.

While the present invention has been particularly shown and described with reference to a method for manufacturing a capacitor, this invention should not be construed as being limited thereto. Rather, the present invention can be applied to any wet etching process involving a chemical solution containing bubbles therein to etch any dielectric structure, in which an electrode or a conductive layer partially protrudes from the top surface of the dielectric structure, without departing from the spirit and scope of the present invention as defined by the following claims.

What is claimed is:

1. An etching method comprising:
forming a first dielectric layer on a semiconductor substrate;
forming an opening in the dielectric layer;
depositing a conductive layer on the first dielectric layer including the opening;
depositing a second dielectric layer overlying the conductive layer within the opening;
planarizing the resulting structure including the conductive layer, until the top surface of the first layer is exposed, to form a capacitor lower electrode having a top end portion;
reducing the top end portion of the electrode; and
thereafter, etching the first and second dielectric layers with a chemical solution.

2. The method of claim 1, wherein the top end portion of the electrode is reduced such that any bubbles included in the chemical solution do not adhere to the electrode.

3. The method of claim 1, wherein reducing the top end portion comprises recessing a top surface of the electrode below the top surface of the first dielectric layer.

4. The method of claim 3, wherein the recessed top surface is at least 500 angstroms below the top surface of the first dielectric layer.

5. The method of claim 1, wherein reducing the top end portion of the electrode comprises leaving a top surface of the electrode substantially level with the top surface of the first dielectric layer.

6. The method of claim 1, wherein reducing the top end portion of the electrode comprises leaving the top surface of the lower electrode slightly above the top surface of the first dielectric layer such that any bubbles included in the chemical solution can be prevented from adhering to the electrode.

7. The method of claim 1, wherein planarizing comprises chemical mechanical polishing (CMP).

8. The method of claim 7, wherein CMP comprises using a slurry having an etch selectivity between the lower electrode and the dielectric layers.

9. The method of claim 7, wherein reducing the top end portion is performed while performing the CMP.

10. The method of claim 1, wherein planarizing comprises an etching back process.

11. The method of claim 10, wherein reducing the top end portion is performed while performing the etching back process.

12. The method of claim 10, wherein etching back comprises using an etchant having an etch selectivity between the lower electrode and the dielectric layers.

13. The method of claim 1, wherein reducing the top end portion comprises dry etching.

14. The method of claim 13, wherein drying etching uses an etchant selected from the group consisting of HB₄, Cl₂, CF₄, C₄F₈, C₅F₈, SF₆, O₂, and combinations thereof.

15. The method of claim 1, wherein reducing the top end portion comprises wet etching.

16. The method of claim 15, wherein wet etching uses a polysilicon etchant.

17. The method of claim 1, further comprising cleaning the first and second dielectric layers including the electrode to reduce etch residues, after planarizing the resulting structure and before reducing the top end portion of the electrode.

18. The method of claim 17, wherein cleaning comprises using HF.

19. The method of claim 1, wherein the capacitor lower electrode is circular or elliptical in plan view.

20. An etching method comprising:
forming a first dielectric layer on a semiconductor substrate;
forming an opening in the dielectric layer;
depositing a conductive layer on the first dielectric layer including the opening;
depositing a second dielectric layer overlying the conductive layer within the opening;
planarizing the resulting structure including the conductive layer, until the top surface of the first layer is exposed, to form a capacitor lower electrode having a top end portion;
after planarizing the resulting structure, reducing the top end portion of the electrode such that any bubbles included in the chemical solution do not adhere to the electrode; and
thereafter, etching the first and second dielectric layers with a chemical solution.

21. The method of claim 20, wherein reducing the top end portion comprises dry etching.

22. The method of claim 21, wherein drying etching uses an etchant selected from the group consisting of HB₄, Cl₂, CF₄, C₄F₈, C₅F₈, SF₆, O₂, and combinations thereof.

23. The method of claim 20, wherein reducing the top end portion comprises wet etching.

24. The method of claim 23, wherein wet etching uses a polysilicon etchant.

25. The method of claim 20, further comprising cleaning the first and second dielectric layers including the electrode to remove etch residues, after planarizing the resulting structure and before reducing the top end portion of the electrode.

26. The method of claim 25, wherein cleaning comprises using HF.

27. The method of claim 20, wherein the capacitor lower electrode is circular or elliptical in plan view.

28. The method of claim 20, wherein reducing the protruding portion comprises recessing a top surface of the electrode below the top surface of the first dielectric layer.

29. The method of claim 28, wherein the recessed top surface is at least 500 angstroms below the top surface of the first dielectric layer.

30. The method of claim 20, wherein reducing the protruding portion comprises leaving the top surface of the electrode substantially level with the top surface of first the dielectric layer.

31. The method of claim 20, wherein the top surface of the lower electrode is slightly above the top surface of the first dielectric layer such that any bubbles included in the chemical solution can be prevented from adhering to the electrode.
